(19) United States
(12) Patent Application Publication
(10) Pub. No.: US 2025/0112156 A1
(43) Pub. Date: Apr. 3, 2025

(54) BARRIER LAYERS FOR INTERCONNECTS

(71) Applicant: Intel Corporation, Santa Clara, CA (US)

(72) Inventor: Gowtham Sriram JAWAHARRAM, Hillsboro, OR (US)

(21) Appl. No.: 18/374,758

(22) Filed: Sep. 29, 2023

(51) Int. Cl. H01L 23/532; H01L 21/768; H01L 23/522

(52) U.S. Cl. CPC H01L 23/53238; H01L 21/76802; H01L 21/76832; H01L 21/76843; H01L 23/5226

(57) ABSTRACT

Barrier layers comprised of alloys of vanadium in tantalum are provided. The barrier layers are useful for conducting interconnects, such as copper interconnects, for semiconductor devices. Interconnects can be in dielectric layers which can be back-end metallization layers.

### FIELD

Descriptions are generally related to semiconductor devices and semiconductor device manufacturing, and more particular descriptions are related semiconductor device interconnects and barrier layers for semiconductor device interconnects.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor chips and chip packages are typically manufactured layer by layer. A semiconductor device layer structure can be complex and material selections are important to limiting device failures during fabrication. Multilevel metal interconnects constitute a large percentage of semiconductor chip features, semiconductor chip backend metallization features, and semiconductor chip package features. Conducting metal interconnects typically include one or more layers between the metal structure and a dielectric layer, such as, for example, a barrier layer. A barrier layer between the metal region and dielectric layer can be important to prevent interaction between the metal in the interconnect and the surrounding dielectric material, such as for example, copper migration into a silicon dioxide (SiO₂) or other dielectric material during repeated device operation. Making increasingly smaller features robust and reliable is an important challenge for semiconductor chip manufacturing.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention.

FIG. 1 shows a section of a semiconductor chip that has conducting interconnects.

FIG. 2 provides an additional example of a section of a semiconductor chip that has conducting interconnects.

FIG. 3 diagrams an exemplary method for manufacturing a barrier layer comprising vanadium and tantalum, for a copper interconnect.

FIG. 4 illustrates an exemplary package assembly.

FIG. 5 provides an exemplary computing system in which examples of barrier layers comprising vanadium and tantalum can be employed.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following after some other event or events. Other sequences of operations can also be performed according to alternative embodiments. Furthermore, additional operations may be added or removed depending on the particular application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as physical operations. Physical operations include operations performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, microelectronic chip, microelectronic die, IC (integrated circuit) chip, IC die, or semiconductor chip are used interchangeably and refer to a semiconductor device comprising integrated circuits.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard or other printed circuit board for I/O (input/output) communication and power delivery. A package with multiple dies can, for example, be a system in a package.

A package substrate generally includes dielectric layers or structures having conductive structures on and/or embedded within the dielectric layers or structures. The dielectric layers can be, for example, build-up layers. Other structures or devices are also possible within a package substrate. Semiconductor package substrates can have cores or be coreless.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. A package core can, for example, comprise glass (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy).

In further examples of a package substrate core, the substrate core is a glass core comprising an amorphous solid glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what is referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip.

Semiconductor chip interconnects for BEOL processes can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with airgaps. Dielectric layers that include conducting features can be intermetal dielectric (ILD) features.

Barrier layers are employed between a metal of an interconnect, such as, for example, copper, and a neighboring dielectric material. A barrier layer can be comprised of tantalum (Ta) or tantalum nitride (TaN). Barrier layers that are thin films of Ta that have been grown on a dielectric material are typically in the beta phase, i.e., they are a Ta material that exhibits a tetragonal crystal structure. The beta phase of Ta has a higher resistivity than the alpha phase (Ta material that exhibits a body-centered cubic crystal structure). Beta phase Ta can exhibit a resistivity of 180 to 220 μΩ-cm in comparison to the alpha phase of Ta which can exhibit a resistivity of 24 to 50 μΩ-cm. Adding a layer of TiN between a Ta layer and the dielectric layer to form a barrier layer, increases the resistivity of the barrier layer and therefore the interconnect, which can be an undesirable result for an interconnect structure.

The electrical resistivity of a conducting interconnect comprised of copper can be calculated according to Equation 1:

$$R = \frac{4}{π {D}^{2}} [ ( {ρ}_{Cu} ) ( Via Height ) + ( {ρ}_{barrier} ) ( Barrier Thickness ) ] \qquad ( 1 )$$

where R is the electrical resistivity of a copper interconnect, D is the radius of the via, ρ_{Cu} is the resistivity of copper, and ρ_{barrier} is the resistivity of the barrier layer material. Using the following values in Equation 1, via radius (D) is 50 nm, ρ_{CU} is 17 μΩ-cm, via height is 100 nm, ρ_{barrier} for a tetragonal (beta phase) Ta barrier layer is 200 μΩ-cm, and the tetragonal Ta barrier layer is 5 nm thick, yields a resistance of about 14Ω. If the barrier layer is instead a layer comprised of an alloy of about 15 at % vanadium (V) in Ta having a resistivity (ρ_{barrier}) of 22.5 μΩ-cm and the other values remain the same, the resistance of the conducting interconnect via is calculated to be about 9Ω. Thus, according to this calculation, using an alloy of V in Ta reduces the resistivity of a copper interconnect via about 35%. The electrical resistivity of a barrier layer comprising V and Ta decreases with decreased V composition (due to the smaller atomic radius of V (3.03 angstroms) compared to that of Ta (3.3 angstroms)). Therefore, according to a calculation using the above values for Equation 1, except substituting the value for a barrier layer comprised of an alloy having 5 to 10 at % V in Ta that has a ρ_{barrier} of 12.5 μΩ-cm, would provide a conducting interconnect having a resistance of less than 5Ω.

Solid alloys of Ta and V can be used as barrier layers for metal interconnect structures in semiconductor chips and semiconductor chip package applications. For example, solid alloys of Ta and V can be alloys having 0.5 to 20 at % of V in Ta, 1 to 20 at % V in Ta, 5 to 20 at % V in Ta, alloys having 5 to 15 at % V in Ta, or 1 to 10 at % V in Ta. Alloys of Ta and V can exhibit exemplary resistivities of 11 to 25 μΩ-cm for a V concentration of 5 to 20 at % in Ta. These solid alloys can also be referred to as solid solutions or alloys. Reduced resistivity in a barrier layer can reduce the overall resistivity of an interconnect structure.

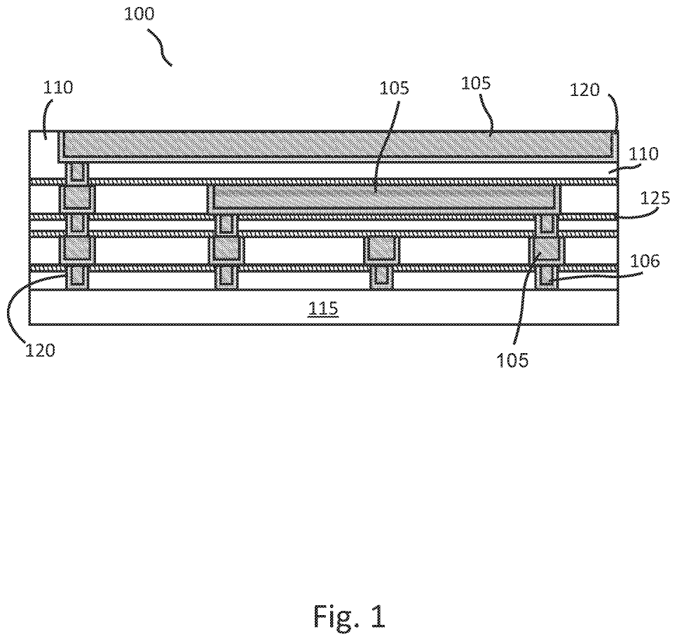

FIG. 1 shows a section of a semiconductor chip 100. In FIG. 1, exemplary conducting interconnects that include trench interconnects 105 and via interconnects 106 are in dielectric layers 110 on a portion of a device-containing section 115 of a semiconductor chip 100. Dielectric layers 110 can be ILDs. Conducting trench interconnects 105 and via interconnects 106 are comprised of a conducting material, such as, for example, copper. The section of the semiconductor chip 100 of FIG. 1 additionally includes barrier layers 120 between the conducting trench interconnects 105 and via interconnects 106 and the dielectric layers 110 and also etch stop layers 125 between the dielectric layers 110. The barrier layers 120 are alloys of Ta and V. For example, alloys of Ta and V can be solid alloys having 0.5 to 20 at % of V in Ta, 1 to 20 at % V in Ta, 5 to 20 at % V in Ta, 5 to 15 at % V in Ta, or 1 to 10 at % V in Ta. Exemplary solid alloys of Ta and V (5 to 20 at % V in Ta) can exhibit resistivities of 11 to 25 μΩ-cm.

The etch stop layers 125 of FIG. 1 can be a material such as, for example, silicon nitride, silicon carbide, and/or silicon carbonitride. In additional examples, etch stop layers 125 can comprise Ta, V, and nitrogen (N). An exemplary etch stop layer 125 can comprise 25 to 65 at % N, 70 to 15 at % Ta, and 5 to 20 at % V. The device-containing section 115 of a semiconductor chip can be the section that is manufactured as the FEOL section that includes circuitry and devices such as, for example, transistors, capacitors, resistors, and/or memory cells (not shown). A device-containing section 115 of the semiconductor chip 100 can be one that was manufactured with CMOS processes. Only a small portion of an actual semiconductor chip is shown for clarity. The conducting trench interconnects 105 and via interconnects 106 in dielectric layers 110 of FIG. 1 can be manufactured by, for example, a damascene process.

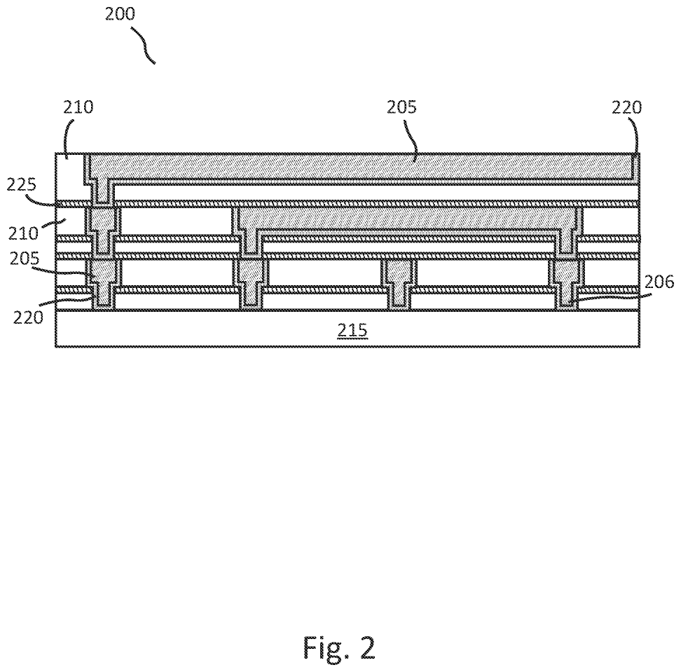

FIG. 2 provides another example of a section of a semiconductor chip 200. In FIG. 2, exemplary conducting interconnects include trench interconnects 205 that are continuous with via interconnects 206. Conducting trench interconnects 205 and via interconnects 206 are in dielectric layers 210 on a portion of a device-containing section 215 of a semiconductor chip 200. Dielectric layers 210 can be ILDs. Conducting trench interconnects 205 and via interconnects 206 are comprised of a conducting material, such as, for example, copper. The section of the semiconductor chip 200 of FIG. 2 additionally includes barrier layers 220 between the conducting trench interconnects 205 and via interconnects 206 and the dielectric layers 210 and also etch stop layers 225 between the dielectric layers 210. The barrier layers 220 are alloys of Ta and V. For example, alloys of Ta and V can be solid alloys having 0.5 to 20 at % of V in Ta, 1 to 20 at % V in Ta, 5 to 20 at % V in Ta, 5 to 15 at % V in Ta, or 1 to 10 at % V in Ta. Exemplary solid alloys of Ta and V (5 to 20 at % V in Ta) can exhibit resistivities of 11 to 25 μΩ-cm.

In FIG. 2, the etch stop layers 225 can be a material such as, for example, silicon nitride, silicon carbide, and/or silicon carbonitride. In additional examples, etch stop layers 225 can comprise Ta, V, and N. An exemplary etch stop layer 225 can comprise 25 to 65 at % N, 70 to 15 at % Ta, and 5 to 20 at % V. A device-containing portion 215 of a semiconductor chip can be the section that is manufactured as the FEOL section that includes circuitry and devices such as, for example, transistors, capacitors, resistors, and/or memory cells (not shown). A device-containing section 215 of the semiconductor chip 100 can be one that was manufactured with CMOS processes. Only a small portion of an actual semiconductor chip is shown for clarity. The conducting trench interconnects 205 and via interconnects 205 in dielectric layers 210 of FIG. 2 can be manufactured by, for example, a dual damascene process.

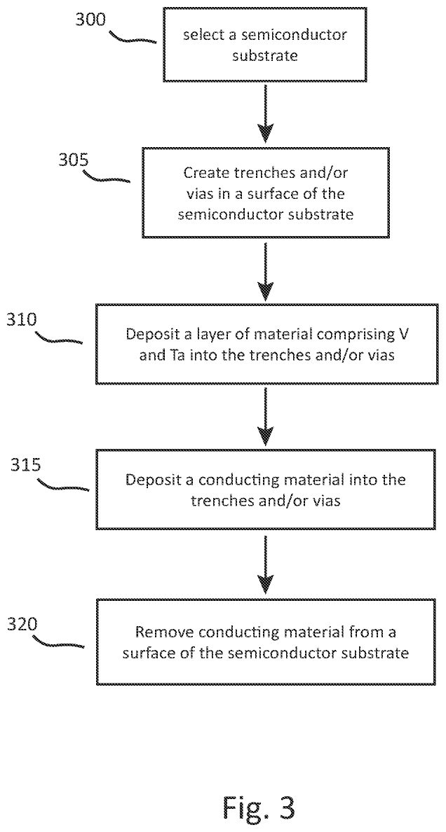

FIG. 3 provides a diagram of an exemplary process for manufacturing a conducting trench and/or via interconnect having a barrier layer comprised of V and Ta. In FIG. 3, a semiconductor substrate is selected 300. The semiconductor substrate can be, for example, a partially manufactured semiconductor chip comprising, for example, electronic circuits and active and passive devices, such as for example, transistors, capacitors, resistors, and/or memory cells. Further manufacturing processes performed on the semiconductor substrate can be, for example, the creation of layers forming interconnects in BEOL processes. Trenches and/or vias are created in a surface of the semiconductor substrate 305. The surface of the semiconductor substrate can comprise, for example, a dielectric layer. The dielectric layer can be a low-K dielectric material or other insulating material as described herein. The surface can also comprise etch stop layers that can be a material such as, for example, silicon nitride, silicon carbide, and/or silicon carbonitride. In additional examples, etch stop layers can comprise Ta, V, and nitrogen (N). An exemplary etch stop layer can comprise 25 to 65 at % N, 70 to 15 at % Ta, and 5 to 20 at % V. A barrier layer comprising V and Ta is deposited into the trenches and/or vias 310. The barrier layer can be, for example, a solid alloy having 0.5 to 20 at % of V in Ta, 1 to 20 at % V in Ta, 5 to 20 at % V in Ta, 5 to 15 at % V in Ta, or 1 to 10 at % V in Ta. The barrier layer comprising V and Ta can be deposited using a physical vapor deposition process and DC (direct current) magnetron sputtering. During barrier layer deposition, optionally the substrate bias (AC (alternating current) bias) is varied. Varying the substrate bias during deposition can vary the degree of adhesion of the barrier layer to the dielectric layer. Also optionally, the deposition power can be varied to vary the rate of deposition of the barrier layer. A conducting material is then deposited into the trenches and/or vias 315. The conducting material can be copper. Excess conducting material is removed from a surface of the semiconductor substrate 320. The overall process of FIG. 3 can be a damascene or dual damascene process. Devices such as those shown in and described with respect to FIGS. 1 and 2 herein can be created according to the process of FIG. 3.

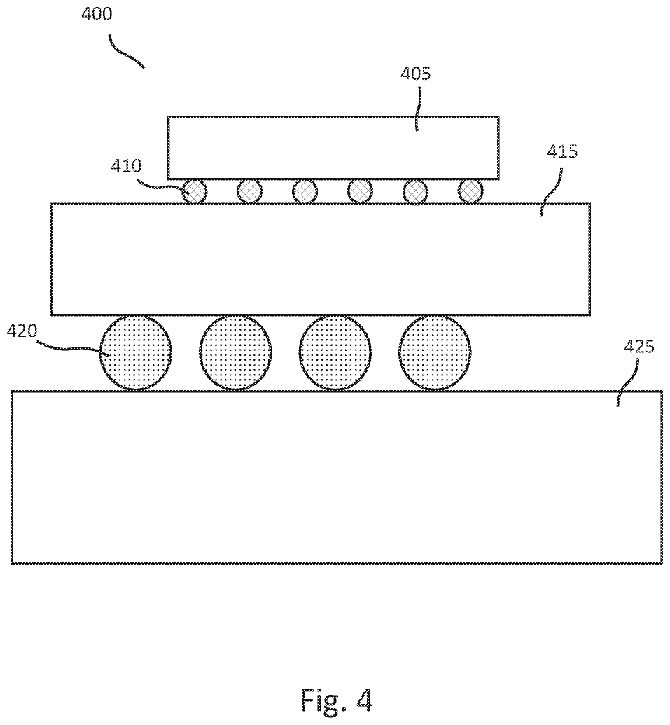

FIG. 4 illustrates a package assembly 400 in which an exemplary semiconductor chip comprising barrier layers of V and Ta can be employed. The package assembly 400 of FIG. 4 includes a semiconductor chip 405, however, the structures shown do not include all features that might be present for the semiconductor chip 405 package and features are not necessary illustrated relatively to scale. For example, a package assembly can include additional semiconductor chips (not shown) and encapsulation (not shown) for the semiconductor chip 405. The semiconductor chip 405 can include barrier layers comprising V and Ta as described herein. The chip 405 is electrically coupled to the package through chip connectors 410. Chip connectors 410 could also be pins, rods, bumps, or types of electrically conductive features used to join the chip 405 to a package substrate 415 and provide power and communication. Package assembly 400 has board-side connectors 420 that are electrically and communicatively attached to contacts on a board 425 (which could be a motherboard, mainboard, main circuit board, printed circuit board, circuit board, system board, or logic board). The board-side connectors 420 can be solder balls, pins, pads, or other types of electrical contacts. The board-side connectors 420 can be a ball grid array (BGA), land grid array (LGA) or pin grid array (PGA) or for use with a LGA or PGA or for coupling to a socket feature of a board 425.

Motherboards (or board, mainboard, main circuit board, printed circuit board, circuit board, system board, or logic board) such as those shown in FIG. 4 provide electrical contacts, i.e., power delivery and communication routes. Numerous electronic components can be housed on a motherboard, including processors (Central Processing Units (CPUs), graphics processing units (GPUs), digital signal processors (DSPs), coprocessors, network processors, etc.), accelerators, memory controllers, application-specific integrated circuits (ASICs), interface controllers, chipsets, systems in a chip, dual in-line memory modules (DIMMs) or RAM, non-volatile memory, power input and delivery connections, clock generators, BIOS (basic input/output system) chips, and interfaces and connectors peripherals and memory storage devices. The motherboard may contain slots or other types of connectors that accept DIMM or RAM cards, graphics cards or expansion cards. Additional connectors include, for example, Serial Advanced Technology Attachment (SATA) ports, and Peripheral Component Interconnect (PCI) and PCIe (PCI express) slots. Connectors for I/O devices such as peripherals can include, for example, high-definition multimedia interfaces (HDMI), Institute of Electrical and Electronics Engineers (IEEE) standard 1394 bus (Firewire) and universal serial bus (USB) connection receivers for mice, keyboards, storage devices, displays, and cameras, among other devices.

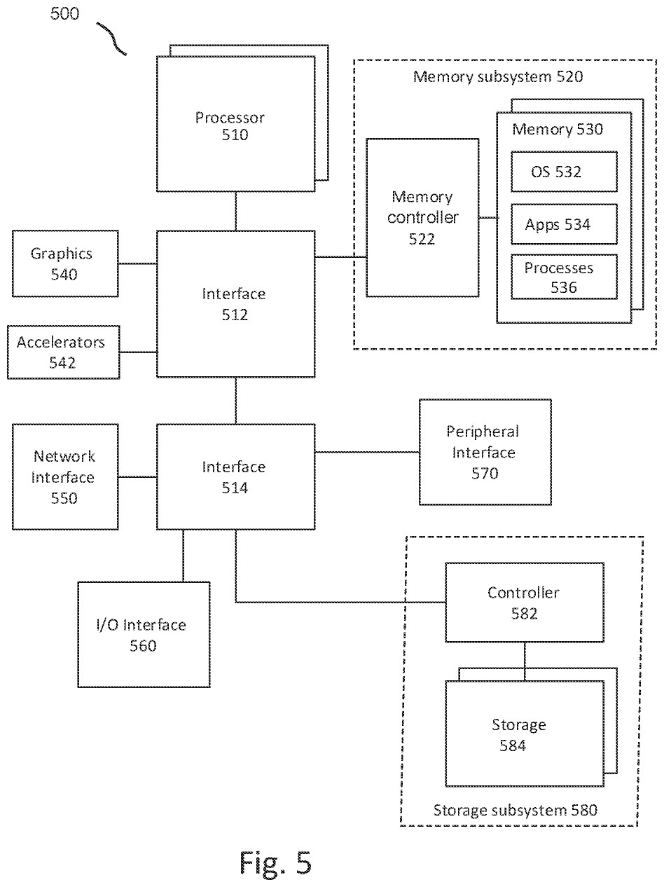

FIG. 5 depicts an example computing system which exemplary semiconductor chips having barrier layers comprising V and Ta can be employed. The semiconductor chips can be for example, one or more processors, accelerators, and/or memory chips. The computing system employed can include more, different, or fewer features than the one described with respect to FIG. 5.

Computing system 500 includes processor 510, which provides processing, operation management, and execution of instructions for system 500. Processor 510 can include any type of microprocessor, CPU (central processing unit), GPU (graphics processing unit), processing core, or other processing hardware to provide processing for system 500, or a combination of processors or processing cores. Processor 510 controls the overall operation of system 500, and can be or include, one or more programmable general-purpose or special-purpose microprocessors, DSPs, programmable controllers, ASICs, programmable logic devices (PLDs), or the like, or a combination of such devices.

In one example, system 500 includes interface 512 coupled to processor 510, which can represent a higher speed interface or a high throughput interface for system components needing higher bandwidth connections, such as memory subsystem 520 or graphics interface components 540, and/or accelerators 542. Interface 512 represents an interface circuit, which can be a standalone component or integrated onto a processor die. Where present, graphics interface 540 interfaces to graphics components for providing a visual display to a user of system 500. In one example, the display can include a touchscreen display.

Accelerators 542 can be a fixed function or programmable offload engine that can be accessed or used by a processor 510. For example, an accelerator among accelerators 542 can provide data compression (DC) capability, cryptography services such as public key encryption (PKE), cipher, hash/authentication capabilities, decryption, or other capabilities or services. In some cases, accelerators 542 can be integrated into a CPU socket (e.g., a connector to a motherboard (or circuit board, printed circuit board, mainboard, system board, or logic board) that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 530 stores and hosts, among other things, operating system (OS) 532 that provides a software platform for execution of instructions in system 500, and stores and hosts applications 534 and processes 536. In one example, memory subsystem 520 includes memory controller 522, which is a memory controller to generate and issue commands to memory 530. The memory controller 522 could be a physical part of processor 510 or a physical part of interface 512. For example, memory controller 522 can be an integrated memory controller, integrated onto a circuit within processor 510.

System 500 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe), a Hyper Transport or industry standard architecture (ISA) bus, a small computer system interface (SCSI) bus, a universal serial bus (USB), or a Firewire bus.

In one example, system 500 includes interface 514, which can be coupled to interface 512. In one example, interface 514 represents an interface circuit, which can include standalone components and integrated circuitry. In one example, user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB, or other wired or wireless standards-based or proprietary interfaces. Network interface 550 can transmit data to a device that is in the same data center or rack or a remote device, which can include sending data stored in memory.

Some examples of network interface 550 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include additional types of hardware interfaces, such as, for example, interfaces to semiconductor fabrication equipment and/or electrostatic charge management devices.

In one example, system 500 includes storage subsystem 580. Storage subsystem 580 includes storage device(s) 584, which can be or include any conventional medium for storing data in a nonvolatile manner, such as one or more magnetic, solid state, and/or optical based disks. Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 512 or processor 510 or can include circuits or logic in both processor 510 and interface 514.

A power source (not depicted) provides power to the components of system 500. More specifically, power source typically interfaces to one or multiple power supplies in system 500 to provide power to the components of system 500.

Exemplary systems may be implemented in various types of computing, smart phones, tablets, personal computers, and networking equipment, such as switches, routers, racks, and blade servers such as those employed in a data center and/or server farm environment.

Additional examples include a semiconductor chip comprising a dielectric layer, a trench in the dielectric layer, a conducting material comprising copper in the trench; and a barrier layer comprising an alloy of V and Ta, wherein the barrier layer is between the conducting material and the dielectric layer. The semiconductor chip can have an alloy of V and Ta that comprises 0.5 to 20 at % of V in Ta. The semiconductor chip can have an alloy of V and Ta comprises 5 to 20 at % of V in Ta. The semiconductor chip can additionally comprise an etch stop layer wherein the etch stop layer comprises V, Ta, and N. The semiconductor chip can have a dielectric layer that comprises a low-K dielectric material. The semiconductor chip can have a dielectric layer that comprises silicon dioxide, silicon nitride, silicon carbide, or silicon carbonitride. The semiconductor chip can have a dielectric layer that comprises fluorine-doped silicon dioxide, carbon-doped silicon dioxide, or porous silicon dioxide.

Further examples include a semiconductor device comprising a dielectric layer, a via in the dielectric layer, a conducting material comprising copper in the via; and a barrier layer comprising an alloy of V and Ta, wherein the barrier layer is between the conducting material and the dielectric layer. The semiconductor device can have an alloy of V and Ta that comprises 0.5 to 20 at % of V in Ta. The semiconductor device can have an alloy of V and Ta comprises 5 to 20 at % of V in Ta. The semiconductor device can additionally comprise an etch stop layer wherein the etch stop layer comprises V, Ta, and N. The semiconductor device can have a dielectric layer that comprises a low-K dielectric material. The semiconductor device can have a dielectric layer that comprises silicon dioxide, silicon nitride, silicon carbide, or silicon carbonitride. The semiconductor device can have a dielectric layer that comprises fluorine-doped silicon dioxide, carbon-doped silicon dioxide, or porous silicon dioxide.

An example method for manufacturing a semiconductor device is also provided. The example method for manufacturing a semiconductor device comprises creating a via in a surface of a semiconductor device wherein the surface comprises a dielectric layer, depositing a layer of material comprising V and Ta into the via depositing a conducting material comprising copper into the via, and removing the conducting material comprising copper from a surface of the semiconductor device. In this method, the layer of material comprising V and Ta can comprise 5 to 20 at % V in Ta. The layer of material comprising V and Ta can comprise 0.5 to 20 at % V in Ta. The dielectric layer can comprise a low-K dielectric material. The dielectric layer can comprise silicon dioxide, silicon nitride, silicon carbide, or silicon carbonitride. The dielectric layer can comprise fluorine-doped silicon dioxide, carbon-doped silicon dioxide, or porous silicon dioxide.

A further example method for manufacturing a semiconductor device is provided. The example method for manufacturing a semiconductor device comprises creating a trench in a surface of a semiconductor device wherein the surface comprises a dielectric layer, depositing a layer of material comprising V and Ta into the trench depositing a conducting material comprising copper into the trench, and removing the conducting material comprising copper from a surface of the semiconductor device. In this method, the layer of material comprising V and Ta can comprise 5 to 20 at % V in Ta. The layer of material comprising V and Ta can comprise 0.5 to 20 at % V in Ta. The dielectric layer can comprise a low-K dielectric material.

An example assembly can comprise a semiconductor chip wherein the semiconductor chip comprises a dielectric layer, the dielectric layer comprises a via, and the via comprises a barrier layer comprising an alloy of V and Ta and the barrier layer is between the dielectric layer and a conducting region comprising copper in the via, and a package substrate wherein the package substrate is coupled to the semiconductor chip. The assembly can also comprise a circuit board wherein the circuit board is coupled to the package substrate. The assembly can have an alloy of V and Ta that comprises 5 to 20 at % V in Ta. The assembly can have an alloy of V and Ta that comprises 0.5 to 20 at % V in Ta. The assembly can also comprise a circuit board wherein the circuit board additionally comprises a DIMM.

An example assembly can comprise a semiconductor chip wherein the semiconductor chip comprises a dielectric layer, the dielectric layer comprises a trench, and the trench comprises a barrier layer comprising an alloy of V and Ta and the barrier layer is between the dielectric layer and a conducting region comprising copper in the trench, and a package substrate wherein the package substrate is coupled to the semiconductor chip. The assembly can also comprise a circuit board wherein the circuit board is coupled to the package substrate. The assembly can have an alloy of V and Ta that comprises 5 to 20 at % V in Ta. The assembly can have an alloy of V and Ta that comprises 0.5 to 20 at % V in Ta. The assembly can also comprise a circuit board wherein the circuit board additionally comprises a DIMM.

Besides what is described herein, various modifications can be made to what is disclosed without departing from the scope of the examples illustrated. Therefore, the illustrations and examples herein should be construed in an illustrative, and not a restrictive sense.

What is claimed is:

1. A semiconductor chip comprising:
a dielectric layer;
a trench in the dielectric layer;
a conducting material comprising copper in the trench; and
a barrier layer comprising an alloy of V and Ta, wherein the barrier layer is between the conducting material and the dielectric layer.

2. The semiconductor chip of claim 1 wherein the alloy of V and Ta comprises 0.5 to 20 at % of V in Ta.

3. The semiconductor chip of claim 1 wherein the alloy of V and Ta comprises 5 to 20 at % V in Ta.

4. The semiconductor chip of claim 1 additionally comprising an etch stop layer wherein the etch stop layer comprises V, Ta, and N.

5. The semiconductor chip of claim 1, wherein the dielectric layer comprises a low-K dielectric material.

6. The semiconductor chip of claim 1 wherein the dielectric layer comprises silicon dioxide, silicon nitride, silicon carbide, or silicon carbonitride.

7. The semiconductor chip of claim 1 wherein the dielectric layer comprises fluorine-doped silicon dioxide, carbon-doped silicon dioxide, or porous silicon dioxide.

8. A semiconductor device comprising:
a dielectric layer;
a via in the dielectric layer;
a conducting material comprising copper in the via; and
a barrier layer comprising an alloy of V and Ta, wherein the barrier layer is between the conducting material and the dielectric layer.

9. The semiconductor device of claim 8 wherein the alloy of V and Ta comprises 0.5 to 20 at % of V in Ta.

10. The semiconductor device of claim 8 wherein the alloy of V and Ta comprises 5 to 20 at % V in Ta.

11. The semiconductor device of claim 8 additionally comprising an etch stop layer wherein the etch stop layer comprises V, Ta, and N.

12. The semiconductor device of claim 8, wherein the dielectric layer comprises a low-K dielectric material.

13. The semiconductor device of claim 8 wherein the dielectric layer comprises silicon dioxide, silicon nitride, silicon carbide, or silicon carbonitride.

14. The semiconductor device of claim 8 wherein the dielectric layer comprises fluorine-doped silicon dioxide, carbon-doped silicon dioxide, or porous silicon dioxide.

15. A method for manufacturing a semiconductor device comprising:
creating a via in a surface of a semiconductor device wherein the surface comprises a dielectric layer;
depositing a layer of material comprising V and Ta into the via;
depositing a conducting material comprising copper into the via; and
removing the conducting material comprising copper from a surface of the semiconductor device.

16. The method of claim 15 wherein the layer of material comprising V and Ta comprises 5 to 20 at % V in Ta.

17. The method of claim 15 wherein the dielectric layer comprises a low-K dielectric material.

18. An assembly comprising:
a semiconductor chip wherein the semiconductor chip comprises a dielectric layer, the dielectric layer comprises a via, and the via comprises a barrier layer comprising an alloy of V and Ta and the barrier layer is between the dielectric layer and a conducting region comprising copper in the via; and
a package substrate wherein the package substrate is coupled to the semiconductor chip.

19. The assembly of claim 18 wherein the alloy of V and Ta comprises 5 to 20 at % V in Ta.

20. The assembly of claim 18 additionally comprising a circuit board wherein the circuit board is coupled to the package substrate.
